(19) United States
(12) Patent Application Publication
(10) Pub. No.: US 2024/0107796 A1
(43) Pub. Date: Mar. 28, 2024

(54) LIGHT-EMITTING DEVICE AND DISPLAY APPARATUS, IMAGING APPARATUS, ELECTRONIC DEVICE, ILLUMINATION APPARATUS, AND MOVING OBJECT INCLUDING THE SAME

(71) Applicant: CANON KABUSHIKI KAISHA, Tokyo (JP)

(72) Inventor: TAKASHI TSUBOI, Kanagawa (JP)

(21) Appl. No.: 18/521,992

(22) Filed: Nov. 28, 2023

Related U.S. Application Data
(63) Continuation of application No. PCT/JP2022/020581, filed on May 17, 2022.

(30) Foreign Application Priority Data
May 31, 2021 (JP) 2021-091338

(51) Int. Cl. H10K 50/844; H10K 59/38

(52) U.S. Cl. CPC H10K 50/844; H10K 59/38

(57) ABSTRACT

A light-emitting device includes a light-emitting element, and a protection layer covering the light-emitting element and composed of an inorganic compound, wherein a light absorption rate of the protection layer at a wavelength of 450 nm is less than 7%, and the light absorption rate of the protection layer at a wavelength of 380 nm is 5% or more.

### CROSS-REFERENCE TO RELATED APPLICATIONS

This application is a Continuation of International Patent Application No. PCT/JP2022/020581, filed May 17, 2022, which claims the benefit of Japanese Patent Application No. 2021-091338, filed May 31, 2021, both of which are hereby incorporated by reference herein in their entirety.

### BACKGROUND OF THE INVENTION

### Field of the Invention

The present invention relates to a light-emitting device including a pair of electrodes and an organic compound layer containing a light-emitting layer between the pair of electrodes and a display apparatus, an imaging apparatus, an electronic device, an illumination apparatus, and a moving object including the same.

### Background Art

In recent years, as a flat panel display, a self-light emission device draws attention owing to its contrast and high degree of freedom in design. It is known that in a light-emitting element of a light emission device, a protection layer is provided to reduce the influence from outside of an apparatus. Particularly, the characteristics of an organic light-emitting element in which an organic compound is used as the constituent material of a light-emitting element are likely to deteriorate due to moisture or oxygen, and can cause the occurrence of a dark spot, which is a non-light-emitting point, under the influence of a small amount of moisture.

It is known that a protection layer is provided to stably drive an organic light-emitting element of an organic light-emitting device for a long period. The protection layer is provided to reduce the entry of moisture or oxygen into an organic compound layer. It is known that an inorganic compound such as silicon nitride, silicon oxynitride, silicon oxide, or aluminum oxide is used in such a protection layer. Further, these protection layers are required to absorb light in the ultraviolet region to reduce the deterioration of the organic compound layer.

PTL 1 discusses a technique in which the absorption rate at a wavelength of 405 nm is 25% or more due to an organic layer provided on an upper electrode of an organic light-emitting element.

PTL 2 discusses a technique in which the light transmittance at a wavelength of 313 nm is 30% or less between an organic electroluminescent (EL) element and a touch panel due to an organic layer provided on the organic EL element.

### CITATION LIST

### Patent literature

PTL 1: United States Patent No. 10084157

PTL 2: Japanese Patent Application Laid-Open No. 2018-147812

PTLs 1 and 2 discusses an organic light-emitting element that absorbs ultraviolet light using a layer including an organic layer. An organic compound, however, also absorbs light in the visible light region, and therefore may reduce the efficiency of a light-emitting device. The organic compound can also deteriorate due to ultraviolet light, and therefore has an issue with maintaining the function of a protection layer over a long period.

### SUMMARY OF THE INVENTION

In view of the above issue, the present invention is directed to providing a light-emitting device including a protection layer that protects a light-emitting element over a long period.

According to an aspect of the present invention, a light-emitting device includes a light-emitting element, and a protection layer covering the light-emitting element and composed of an inorganic compound, wherein a light absorption rate of the protection layer at a wavelength of 450 nm is less than 7%, and the light absorption rate of the protection layer at a wavelength of 380 nm is 5% or more.

Further features of the present invention will become apparent from the following description of exemplary embodiments with reference to the attached drawings.

### BRIEF DESCRIPTION OF THE DRAWINGS

FIG. 1A is a schematic diagram illustrating a light-emitting device according to a first exemplary embodiment.

FIG. 1B is a schematic diagram illustrating a light-emitting device according to a second exemplary embodiment.

FIG. 1C is a schematic diagram illustrating a light-emitting device according to a third exemplary embodiment.

FIG. 2A is a schematic cross-sectional view illustrating an example of a pixel of a display apparatus according to an exemplary embodiment of the present invention.

FIG. 2B is a schematic cross-sectional view illustrating an example of a display apparatus using an organic light-emitting element according to an exemplary embodiment of the present invention.

FIG. 3A is a schematic diagram illustrating an image forming apparatus according to an exemplary embodiment of the present invention.

FIGS. 3B and 3C are schematic diagrams illustrating forms in which a plurality of light-emitting units of an exposure light source is placed on a long substrate.

FIG. 4 is a schematic diagram illustrating an example of a display apparatus according to an exemplary embodiment of the present invention.

FIG. 5A is a schematic diagram illustrating an example of an imaging apparatus according to an exemplary embodiment of the present invention.

FIG. 5B is a schematic diagram illustrating an example of an electronic device according to an exemplary embodiment of the present invention.

FIG. 6A is a schematic diagram illustrating an example of a display apparatus according to an exemplary embodiment of the present invention.

FIG. 6B is a schematic diagram illustrating an example of a foldable display apparatus.

FIG. 7A is a schematic diagram illustrating an example of an illumination apparatus according to an exemplary embodiment of the present invention.

FIG. 7B is a schematic diagram illustrating an example of an automobile including a lamp fitting for a vehicle according to an exemplary embodiment of the present invention.

FIG. 8A is a schematic diagram illustrating an example of a wearable device according to an exemplary embodiment of the present invention.

FIG. 8B is a schematic diagram illustrating an example of a wearable device according to an exemplary embodiment of the present invention, which is a form including an imaging apparatus.

FIG. 9 is a graph illustrating a wavelength dependence of an absorption rate of a protection layer in example 1.

### DESCRIPTION OF THE EMBODIMENTS

Exemplary embodiments of the present invention will be described in detail below with reference to the drawings. The present invention, however, is not limited to these exemplary embodiments.

A well-known or publicly known technique in this technical field can be applied to portions that are not particularly illustrated or described in the specification.

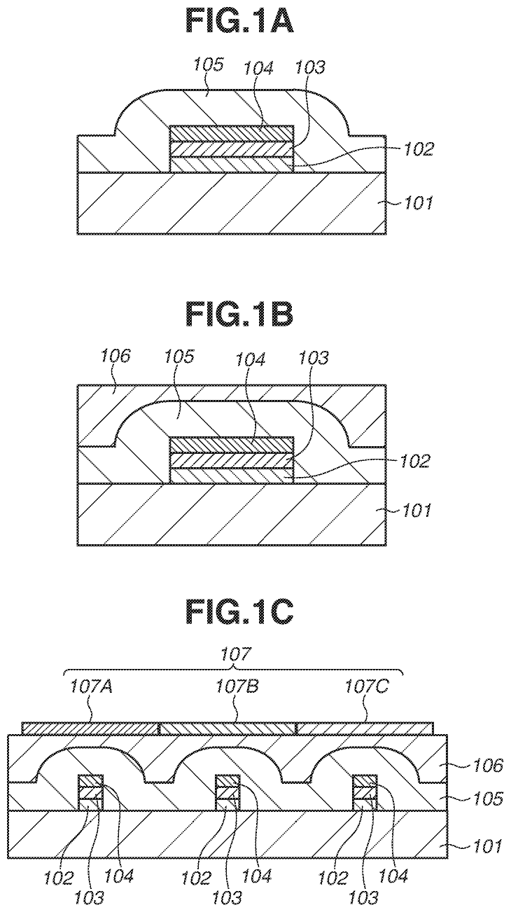

FIG. 1A is a schematic diagram illustrating a light-emitting device according to a first exemplary embodiment of the present invention. In the light-emitting device according to the present exemplary embodiment, a lower electrode 102, a functional layer 103 containing a light-emitting layer, an upper electrode 104, and a protection layer 105 composed of an inorganic compound are disposed in this order on a substrate 101.

The light absorption rate of the protection layer 105 at a wavelength of 450 nm is less than 7%, and the light absorption rate of the protection layer 105 at a wavelength of 380 nm is greater than 5%. Consequently, the absorption of visible light by the protection layer 105 is low, and therefore, the protection layer 105 is a protection layer less likely to absorb light emitted from the light-emitting device. The absorption of light in the ultraviolet region by the protection layer 105 is high, and therefore, the protection layer 105 is a protection layer that reduces the influence of ultraviolet light on a light-emitting element.

It is desirable that the absorption rate of the protection layer 105 at a wavelength of 450 nm should be 5% or less. It is more desirable that the absorption rate of the protection layer 105 at a wavelength of 450 nm should be 1% or less. It is desirable that the absorption rate of the protection layer 105 at a wavelength of 380 nm should be 10% or more. It is more desirable that the absorption rate of the protection layer 105 at a wavelength of 380 nm should be 25% or more. If the absorption rate of the protection layer 105 at a wavelength of 380 nm is 66% or less, the absorption of light in the visible light region by the protection layer 105 is not high, which is desirable.

The rate of dissolution of the protection layer 105 having the above properties in 1% hydrogen fluoride (HF) at 25° C. is 80 nm/min or more and 2000 nm/min or less. The light absorption rate of the protection layer 105 is determined by the molecular structure of the constituents of the protection layer 105. On the other hand, the molecular structure of the constituents of the protection layer 105 influences the etching rate of the protection layer 105. That is, the light absorption rate can be estimated based on the etching rate. If the protection layer 105 includes a plurality of layers, the rate of dissolution of any of the plurality of layers in 1% HF at 25° C. may only need to be 80 nm/min or more and 2000 nm/min or less.

The protection layer 105 is formed to cover the entirety of the lower electrode 102, the functional layer 103, and the upper electrode 104. The protection layer 105 is composed of an inorganic compound. Examples of the constituent material of the protection layer 105 include silicon nitride, silicon oxide, silicon oxynitride, and aluminum oxide. A laminate obtained by laminating a plurality of layers composed of these materials can be used. The protection layer 105 may be composed of a plurality of layers. For example, the plurality of layers may include a first silicon nitride layer, a second silicon nitride layer, a first aluminum oxide layer, and a second aluminum oxide layer. The densities of the first and second silicon nitride layers may be different from each other.

Each of the silicon nitride layers of the protection layer 105 may be a layer composed only of silicon nitride. Similarly, each of the aluminum oxide layers of the protection layer 105 may be a layer composed only of aluminum oxide.

The protection layer 105 may be a layer consisting only of a layer composed only of silicon nitride and a layer composed only of aluminum oxide. The protection layer 105 may be a layer including a first layer composed only of silicon nitride, a layer composed only of aluminum oxide, and a second layer composed only of silicon nitride in this order. Alternatively, the protection layer 105 may be a layer including a layer composed only of aluminum oxide, a first layer composed only of silicon nitride, a layer composed only of aluminum oxide, and a second layer composed only of silicon nitride in this order, or a layer including a layer composed only of aluminum oxide, a first layer composed only of silicon nitride, and a second layer composed only of silicon nitride in this order.

In the protection layer 105, the first layer composed only of silicon nitride may be a layer the rate of dissolution of which in 1% HF at 25° C. is 80 nm/min or more and 2000 nm/min or less.

In the protection layer 105, the first layer composed only of silicon nitride and the second layer composed only of silicon nitride may be layers the rates of dissolution of which in 1% HF at 25° C. are 80 nm/min or more and 2000 nm/min or less.

The protection layer 105 may include a plurality of layers, and the rates of dissolution of all the plurality of layers in 1% HF at 25° C. may be 80 nm/min or more and 2000 nm/min or less.

The layer thickness of the protection layer 105 may be 0.5 μm or more and 5.0 μm or less.

The functional layer 103 contains a light-emitting layer. The light-emitting layer may be an inorganic layer or an organic layer. If the light-emitting layer is an organic layer, a light-emitting element is an organic light-emitting element including a first electrode, the organic layer containing the light-emitting layer, and a second electrode in this order. The protection layer according to the present exemplary embodiment is excellent in protection performance, and therefore can reduce the entry of moisture and the deterioration of an organic layer due to ultraviolet light. Thus, it is particularly desirable that the protection layer according to the present exemplary embodiment should be a protection layer for the organic light-emitting element.

The protection layer according to the present exemplary embodiment is a protection layer with which the light-emitting device hardly causes a light emission failure due to moisture or oxygen even after a high-temperature high-humidity storage test (e.g., 60° C., a relative humidity (RH) of 90%, and 1000 hours). That is, the protection layer according to the present exemplary embodiment is a protection layer that protects a light-emitting element over a long period.

For example, if the protection layer 105 includes a single layer, the light absorption rate of the protection layer 105 can be determined by measuring the film thickness, the refractive index, and the extinction coefficient of a sample obtained by forming a film of only the protection layer 105 on the substrate 101, using an ellipsometer.

If the protection layer 105 is a laminate, the film thickness, the refractive index, and the extinction coefficient of a sample obtained by forming a film of each layer on the substrate 101 can be measured using the ellipsometer. After the absorption rate of each layer is determined based on the measured values, the absorption rate of the protection layer 105 can be determined by calculating the absorption rates of the respective layers.

FIG. 1B is a schematic diagram illustrating a light-emitting device according to a second exemplary embodiment. The light-emitting device according to the second exemplary embodiment has a configuration in which a resin layer 106 is provided on the protection layer 105 in the light-emitting device according to the first exemplary embodiment. The resin layer 106 may be provided for the purpose of planarizing unevenness that occurs in the manufacturing process up to formation of the protection layer 105. To that end, the resin layer 106 may be a planarization layer.

FIG. 1C is a schematic diagram illustrating a light-emitting device according to a third exemplary embodiment. The light-emitting device according to the third exemplary embodiment includes a color filter layer 107 on the resin layer 106 in the light-emitting device according to the second exemplary embodiment. The color filter layer 107 includes color filters 107A, 107B, and 107C. The wavelengths of light passing through the color filters 107A, 107B, and 107C, i.e., the colors of the color filters 107A, 107B, and 107C, are different from each other. The color filters 107A to 107C are provided with respect to each pixel.

In the present exemplary embodiment, the functional layer 103 is separated with respect to each pixel. The present invention, however, is not limited to this form, and the functional layer 103 may be disposed over a plurality of pixels. That is, it may be said that a single functional layer is disposed in the light-emitting device. Similarly, the upper electrode 104 may also be disposed over a plurality of pixels.

### [Configuration of Organic Light-Emitting Element]

An organic light-emitting element is provided by forming an insulating layer, a first electrode, an organic compound layer, and a second electrode on a substrate. On a cathode, a protection layer, a color filter, and a microlens may be provided. In a case where the color filter is provided, a planarization layer may be provided between the color filter and the protection layer. The planarization layer can be composed of an acrylic resin. The same applies to a case where a planarization layer is provided between the color filter and the microlens.

### [Substrate]

Examples of the substrate include quartz, glass, a silicon wafer, a resin, and a metal. On the substrate, a switching element such as a transistor and wiring may be provided. On the switching element and the wiring, an insulating layer may be provided. The material of the insulating layer does not matter so long as a contact hole can be formed so that wiring can be formed between the insulating layer and the first electrode, and insulation with wiring to which the insulating layer is not connected can be ensured. For example, a polyimide resin, silicon oxide, or silicon nitride can be used.

### [Electrodes]

As the electrodes, a pair of electrodes can be used. The pair of electrodes may be an anode and a cathode. In a case where an electric field is applied in the direction in which the organic light-emitting element emits light, an electrode having a high potential is the anode, and the other is the cathode. It can also be said that an electrode that supplies holes to a light-emitting layer is the anode, and an electrode that supplies electrons to the light-emitting layer is the cathode.

It is desirable that the constituent material of the anode should have as great a work function as possible. For example, a metal simple substance such as gold, platinum, silver, copper, nickel, palladium, cobalt, selenium, vanadium, or tungsten, a mixture containing these, an alloy obtained by combining these, or a metal oxide such as tin oxide, zinc oxide, indium oxide, indium tin oxide (ITO), or indium zinc oxide can be used. A conductive polymer such as polyaniline, polypyrrole, or polythiophene can also be used.

One type of these electrode substances may be used alone, or two or more types of these electrode substances may be used in combination. The anode may be composed of a single layer, or may be composed of a plurality of layers.

In a case where the anode is used as a reflection electrode, for example, chromium, aluminum, silver, titanium, tungsten, molybdenum, an alloy of these, or a laminate of these can be used. With the above materials, the anode can also function as a reflection film that does not have a role as an electrode. In a case where the anode is used as a transparent electrode, an oxide transparent conductive layer made of indium tin oxide (ITO) or indium zinc oxide can be used. The present invention, however, is not limited to these. A photolithographic technique can be used to form the electrodes.

On the other hand, it is desirable that the constituent material of the cathode should have a small work function. For example, an alkali metal such as lithium, an alkaline earth metal such as calcium, a metal simple substance such as aluminum, titanium, manganese, silver, lead, or chromium, or a mixture containing these can be used. Alternatively, an alloy obtained by combining these metal simple substances can also be used. For example, magnesium-silver, aluminum-lithium, aluminum-magnesium, silver-copper, or zinc-silver can be used. A metal oxide such as indium tin oxide (ITO) can also be used. One type of these electrode substances may be used alone, or two or more types of these electrode substances may be used in combination. The cathode may be composed of a single layer, or may be composed of multiple layers. It is desirable to use silver among these. To reduce the clumping of silver, it is more desirable to use a silver alloy. The ratio of the alloy does not matter so long as the clumping of silver can be reduced. For example, the ratio of silver to the other metal may be 1:1 or 3:1.

The cathode may be a top emission element using an oxide conductive layer made of ITO, or may be a bottom emission element using a reflection electrode made of aluminum (Al). The cathode is not particularly limited. Although a method for forming the cathode is not particularly limited, it is more desirable to use a direct current and alternating current sputtering method because this results in excellent film coverage and facilitates a reduction in resistance.

### [Organic Compound Layer]

The organic compound layer may be formed of a single layer, or may be formed of a plurality of layers. In a case where the organic compound layer includes a plurality of layers, the plurality of layers may be referred to as a “hole injection layer”, a “hole transport layer”, an “electron blocking layer”, a “light-emitting layer”, a “hole blocking layer”, an “electron transport layer”, and an “electron injection layer” according to their functions. The organic compound layer is composed mainly of an organic compound, but may include an inorganic atom or an inorganic compound. For example, the organic compound layer may include copper, lithium, magnesium, aluminum, iridium, platinum, molybdenum, or zinc. The organic compound layer may be placed between the first and second electrodes, and may be disposed in contact with the first and second electrodes.

### [Protection Layer]

On the cathode, a protection layer may be provided. For example, glass in which a moisture absorbent is provided is bonded onto the cathode, whereby it is possible to reduce the entry of water into the organic compound layer and reduce the occurrence of a display failure. As another exemplary embodiment, a passivation film made of silicon nitride may be provided on the cathode, thereby reducing the entry of water into the organic compound layer. For example, after the cathode is formed, the resulting product may be conveyed to another chamber without breaking a vacuum, and a silicon nitride film having a thickness of 2 μm may be formed by a chemical vapor deposition (CVD) method, thereby obtaining a protection layer. After the film is formed by the CVD method, a protection layer may be provided using an atomic layer deposition (ALD) method. The material of the film formed by the ALD method is not limited, but may be silicon nitride, silicon oxide, or aluminum oxide. On the film formed by the ALD method, silicon nitride film may be further formed by the CVD method. The film thickness of the film formed by the ALD method may be smaller than that of the film formed by the CVD method. Specifically, the film thickness of the film formed by the ALD method may be 50% or less, or further, may be 10% or less.

### [Color Filter]

On the protection layer, a color filter may be provided. For example, a color filter taking into account the size of the organic light-emitting element may be provided on another substrate, and the resulting product and the substrate on which the organic light-emitting element is provided may be bonded together. Alternatively, a color filter may be patterned on the protection layer using a photolithographic technique. The color filter may be composed of high molecules.

### [Planarization Layer]

A planarization layer may be included between the color filter and the protection layer. The planarization layer is provided for the purpose of reducing unevenness on a layer below the planarization layer. The planarization layer may also be referred to as a “resin layer” without limiting its purpose. The planarization layer may be composed of an organic compound, and may be composed of low molecules or high molecules. It is, however, desirable that the planarization layer should be composed of high molecules.

Planarization layers may be provided above and below the color filter. The constituent materials of the planarization layers may be the same as or different from each other. Specifically, examples of the constituent materials of the planarization layers include a polyvinyl carbazole resin, a polycarbonate resin, a polyester resin, an acrylonitrile butadiene styrene (ABS) resin, an acrylic resin, a polyimide resin, a phenolic resin, an epoxy resin, a silicon resin, and a urea resin.

### [Microlens]

An organic light-emitting device may include an optical member such as a microlens on its light exit side. The microlens can be composed of an acrylic resin or an epoxy resin. The microlens may be provided for the purpose of increasing the amount of light to be extracted from the organic light-emitting device and controlling the direction of light to be extracted from the organic light-emitting device. The microlens may have a hemispherical shape. In a case where the microlens has a hemispherical shape, there exists a tangent parallel to the insulating layer among tangents touching the hemisphere, and the point of contact between the tangent and the hemisphere is the apex of the microlens. The apex of the microlens can also be similarly determined in any cross-sectional view. That is, there exists a tangent parallel to the insulating layer among tangents touching a semicircle of the microlens in a cross-sectional view, and the point of contact between the tangent and the semicircle is the apex of the microlens.

The midpoint of the microlens can also be defined. In a cross section of the microlens, a line segment from the point where the shape of a circular arc ends to the point where the shape of another circular arc ends is virtualized, and the midpoint of the line segment can be referred to as “the midpoint of the microlens”. The cross sections for determining the apex and the midpoint may be cross sections perpendicular to the insulating layer.

### [Opposing Substrate]

On the planarization layer, an opposing substrate may be included. The opposing substrate is termed “opposing substrate” because the opposing substrate is provided at a position opposing the substrate. The constituent material of the opposing substrate may be the same as that of the substrate. If the substrate is a first substrate, the opposing substrate may be a second substrate.

### [Organic Layer]

An organic compound layer (a hole injection layer, a hole transport layer, an electron blocking layer, a light-emitting layer, a hole blocking layer, an electron transport layer, and an electron injection layer) included in an organic light-emitting element according to an exemplary embodiment of the present invention is formed by a method illustrated below.

The organic compound layer included in the organic light-emitting element according to the exemplary embodiment of the present invention can be formed using a dry process such as a vacuum vapor deposition method, an ionized vapor deposition method, or a sputtering or plasma. Instead of the dry process, a wet process for forming the layer by dissolving a material into an appropriate solvent and performing a known application method (e.g., spin coating, dipping, a casting method, a Langmuir-Blodgett (LB) method, or an inkjet method) can also be used.

If the layer is formed by the vacuum vapor deposition method or the solution application method, crystallization is less likely to occur, and the stability over time is excellent. In a case where the film is formed by the application method, the film can also be formed in combination with an appropriate binder resin.

Examples of the binder resin include a polyvinyl carbazole resin, a polycarbonate resin, a polyester resin, an ABS resin, an acrylic resin, a polyimide resin, a phenolic resin, an epoxy resin, a silicon resin, and a urea resin, but are not limited to these.

One type of these binder resins may be used alone as a homopolymer or a copolymer, or two or more types of these binder resins may be used in a mixed manner. Further, an additive such as a known plasticizer, a known antioxidant, or a known ultraviolet absorber may be used in combination, where necessary.

### [Pixel Circuit]

A light-emitting device may include a pixel circuit connected to a light-emitting element. The pixel circuit may be an active-matrix circuit that independently controls light emission of a first light-emitting element and a second light-emitting element. The active-matrix circuit may perform voltage programming or current programming. A driving circuit includes the pixel circuit with respect to each pixel. The pixel circuit may include a light-emitting element, a transistor that controls the light emission luminance of the light-emitting element, a transistor that controls the light emission timing, a capacitor that holds the gate voltage of the transistor that controls the light emission luminance, and a transistor that connects to the ground (GND) not via the light-emitting element.

The light-emitting device includes a display area and a peripheral area disposed around the display area. The light-emitting device includes the pixel circuit in the display area and includes a display control circuit in the peripheral area. The mobility of each transistor included in the pixel circuit may be smaller than the mobility of each transistor included in the display control circuit.

The slope of the current-voltage characteristic of each transistor included in the pixel circuit may be smaller than the slope of the current-voltage characteristic of each transistor included in the display control circuit. The slope of the current-voltage characteristic can be measured based on a so-called Vg-Ig characteristic.

Each transistor included in the pixel circuit is a transistor connected to a light-emitting element such as the first light-emitting element.

### [Pixels]

The organic light-emitting device includes a plurality of pixels. The pixels include sub-pixels that emit light of colors different from each other. For example, the sub-pixels may have red, green, and blue (RGB) light emission colors.

In each pixel, an area also referred to as a “pixel aperture” emits light. This area is the same as a first area. The pixel aperture may be 15 μm or less, or may be 5 μm or more. More specifically, the pixel aperture may be 11 μm, 9.5 μm, 7.4 μm, or 6.4 μm.

The distance between sub-pixels may be 10 μm or less, and specifically, may be 8 μm, 7.4 μm, or 6.4 μm.

The pixels can take a known arrangement in a plan view. For example, the known arrangement may be the stripe arrangement, the delta arrangement, the PenTile arrangement, or the Bayer arrangement. The shape of each sub-pixel in a plan view may take any known shape. For example, the shape of each sub-pixel is a quadrangle such as a rectangle or a rhombus, or a hexagon. As a matter of course, the rectangle includes a shape close to a rectangle even if the shape is not a precise figure. The shape of each sub-pixel and the pixel arrangement can be used in combination.

### Application of Organic Light-Emitting Element According to Exemplary Embodiment of Present Invention

The organic light-emitting element according to the exemplary embodiment of the present invention can be used as a component member of a display apparatus or an illumination apparatus. Alternatively, the organic light-emitting element can be applied to an exposure light source of an electrophotographic image forming apparatus, a backlight of a liquid crystal display apparatus, or a light-emitting device including a color filter in a white light source.

The display apparatus may be an image information processing apparatus that includes an image input unit to which image information from an area charge-coupled device (CCD), a linear CCD, or a memory card is input, includes an information processing unit that processes the input information, and displays an input image on a display unit.

A display unit included in an imaging apparatus or an inkjet printer may have a touch panel function. A method for driving the touch panel function may be an infrared method, a capacitive method, a resistive method, or an electromagnetic induction method, and is not particularly limited. The display apparatus may be used in a display unit of a multifunction printer.

Next, with reference to the drawings, a display apparatus according to the present exemplary embodiment will be described.

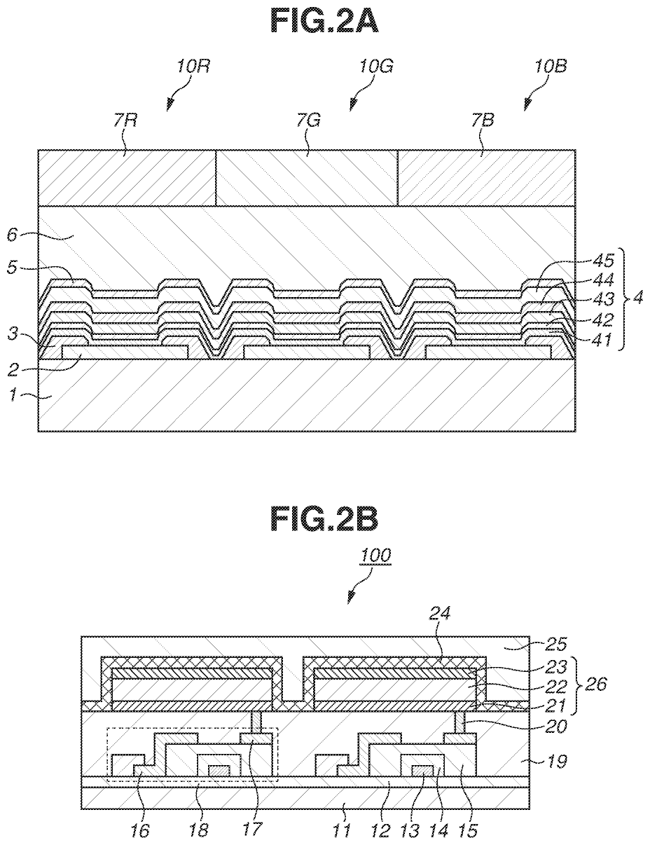

FIGS. 2A and 2B are schematic cross-sectional views illustrating examples of a display apparatus including an organic light-emitting element and a transistor connected to the organic light-emitting element. The transistor is an example of an active element.

The transistor may be a thin-film transistor (TFT).

FIG. 2A is an example of a pixel, which is a component of the display apparatus according to the present exemplary embodiment. The pixel includes a sub-pixel 10. The sub-pixel 10 is divided into sub-pixels 10R, 10G, and 10B based on light emission therefrom. The light emission colors may be distinguished based on wavelengths at which light is emitted from a light-emitting layer, or light emitted from the sub-pixel 10 may be selectively transmitted or subjected to color conversion using a color filter. Each of the sub-pixels 10R, 10G, and 10B includes a reflection electrode 2 as a first electrode, an insulating layer 3 that covers the ends of the reflection electrode 2, an organic compound layer 4 that covers the first electrode 2 and the insulating layer 3, a transparent electrode 5 as a second electrode, a protection layer 6, and a color filter 7 on an interlayer insulating layer 1.

On a layer below the interlayer insulating layer 1 or within the interlayer insulating layer 1, a transistor and a capacitor element may be disposed. The transistor and the first electrode 2 may be electrically connected together via a contact hole (not illustrated).

The insulating layer 3 is also referred to as a “bank” or a “pixel separation film”. The insulating layer 3 covers the ends of the first electrode 2 and is disposed around the first electrode 2. A portion where the insulating layer 3 is not disposed is in contact with the organic compound layer 4 and forms a light emission area.

The organic compound layer 4 includes a hole injection layer 41, a hole transport layer 42, a first light-emitting layer 43, a second light-emitting layer 44, and an electron transport layer 45.

The second electrode 5 may be a transparent electrode, or a reflection electrode, or a semi-transmissive electrode.

The protection layer 6 reduces the penetration of moisture into the organic compound layer 4. Although the protection layer 6 illustrated in FIG. 2A is a single layer, the protection layer 6 may include a plurality of layers. Each layer may be an inorganic compound layer or an organic compound layer.

The color filter 7 is divided into color filters 7R, 7G, and 7B according to its colors. The color filter 7 may be formed on a planarization film (not illustrated). A resin layer (not illustrated) may be disposed on the color filter 7. The color filter 7 may be formed on the protection layer 6. Alternatively, after the color filter 7 is provided on an opposing substrate such as a glass substrate, the opposing substrate and this substrate may be bonded together.

In a display apparatus 100 in FIG. 2B, an organic light-emitting element 26 and a TFT 18 as an example of a transistor are illustrated. A substrate 11 made of glass or silicon is provided, and an insulating layer 12 is provided on the substrate 11. On the insulating layer 12, the active element 18 such as a TFT is disposed, and a gate electrode 13, a gate insulating film 14, and a semiconductor layer 15 of the active element 18 are placed. The TFT 18 also includes a drain electrode 16 and a source electrode 17. On the TFT 18, an insulating film 19 is provided. An anode 21 included in the organic light-emitting element 26 and the source electrode 17 are connected together via a contact hole 20 provided in the insulating film 19.

A method for electrically connecting an electrode (the anode 21 or a cathode 23) included in the organic light-emitting element 26 and an electrode (the source electrode 17 or the drain electrode 16) included in the TFT 18 is not limited to the form illustrated in FIG. 2B. That is, either one of the anode 21 and the cathode 23 may only need to be electrically connected to either one of the source electrode 17 and the drain electrode 16 of the TFT 18. A “TFT” refers to a thin-film transistor.

Although the display apparatus 100 illustrated in FIG. 2B includes a single organic compound layer 22, the display apparatus 100 may include a plurality of organic compound layers 22. On the cathode 23, a first protection layer 24 and a second protection layer 25 for reducing the deterioration of the organic light-emitting element 26 are provided.

Although the display apparatus 100 in FIG. 2B uses a transistor as a switching element, the transistor may be used as another switching element instead.

The transistor used in the display apparatus 100 in FIG. 2B is not limited to a transistor using a monocrystalline silicon wafer, and may be a thin-film transistor including an active layer on an insulating surface of the substrate. Examples of the active layer include monocrystalline silicon, amorphous silicon, non-monocrystalline silicon such as microcrystalline silicon, and non-monocrystalline oxide semiconductors made of indium zinc oxide and indium gallium zinc oxide. The thin-film transistor is also referred to a “TFT element”.

The transistor included in the display apparatus 100 in FIG. 2B may be formed in a substrate such as a silicon (Si) substrate. That the transistor is formed in the substrate means that the transistor is prepared by processing the substrate such as an Si substrate itself. That is, the state where the transistor is included in the substrate can also be regarded as the state where the substrate and the transistor are integrally formed.

The light emission luminance of the organic light-emitting element according to the present exemplary embodiment is controlled by a TFT, which is an example of a switching element, and organic light-emitting elements are provided in a plurality of surfaces, whereby it is possible to display images with the light emission luminances of the respective organic light-emitting elements. The switching element according to the present exemplary embodiment is not limited to a TFT, and may be a transistor formed of low-temperature polysilicon or an active-matrix driver formed on a substrate such as an Si substrate. “On a substrate” can also be said to be “in the substrate”. Whether to provide the transistor in a substrate or use a TFT is selected according to the size of the display unit. If the size of the display unit is about 0.5 inches, for example, it is desirable to provide the organic light-emitting element on an Si substrate.

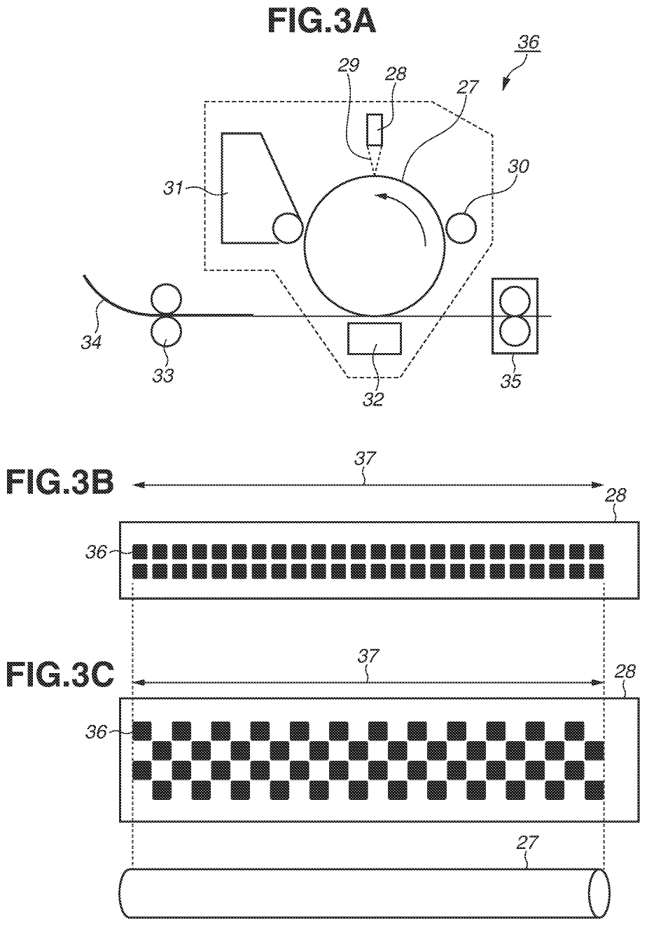

FIGS. 3A, 3B, and 3C illustrate an image forming apparatus according to an exemplary embodiment of the present invention. FIG. 3A is a schematic diagram illustrating an image forming apparatus 36 according to the exemplary embodiment of the present invention. The image forming apparatus 36 includes a photosensitive member 27, an exposure light source 28, a developing unit 31, a charging unit 30, a transfer device 32, a conveying unit 33, and a fixing unit 35.

The exposure light source 28 emits light 29, and an electrostatic latent image is formed on the surface of the photosensitive member 27. The exposure light source 28 includes the organic light-emitting element according to the present invention. The developing unit 31 has toner. The charging unit 30 charges the photosensitive member 27. The transfer device 32 transfers a developed image to a recording medium 34. The conveying unit 33 conveys the recording medium 34. The recording medium 34 is paper, for example. The fixing unit 35 fixes the image formed on the recording medium 34.

FIGS. 3B and 3C are schematic diagrams illustrating the state where a plurality of light-emitting units 36 is placed on a long substrate in the exposure light source 28. An arrow 37 indicates a direction parallel to the axis of the photosensitive member 27 and indicates the column direction in which organic light-emitting elements are arranged. This column direction is the same as the direction of an axis about which the photosensitive member 27 rotates. This direction can also be referred to as “the long axis direction of the photosensitive member 27”.

FIGS. 3B and 3C illustrate forms in which the light-emitting units 36 are placed along the long axis direction of the photosensitive member 27. FIG. 3B illustrates a form different from that in FIG. 3C, and is a form in which light-emitting units 36 are alternately placed in the column direction in each of a first column and a second column. The first and second columns are placed at different positions in the row direction.

In the first column, a plurality of light-emitting units 36 is placed at intervals. The second column has light-emitting units 36 at positions corresponding to the intervals between the light-emitting units 36 in the first column. That is, a plurality of light-emitting units 36 is placed at intervals also in the row direction.

The arrangement in FIG. 3C can be restated as, for example, the state where the light-emitting units 36 are arranged in a grid pattern, the state where the light-emitting units 36 are arranged in a houndstooth pattern, or a checkerboard pattern.

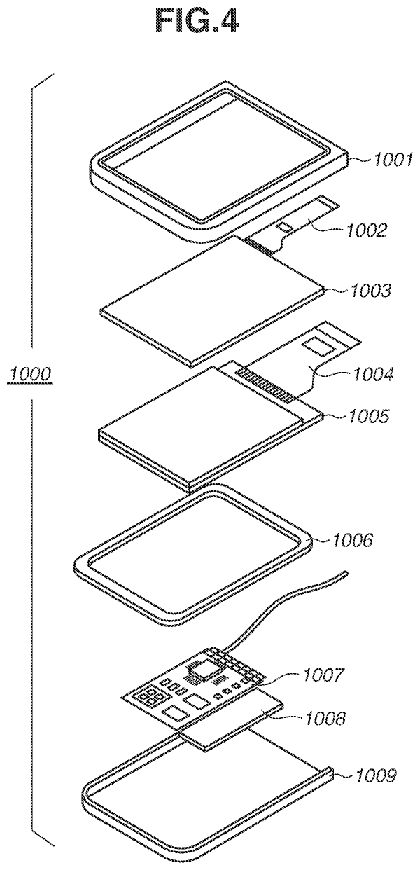

FIG. 4 is a schematic diagram illustrating an example of a display apparatus according to the present exemplary embodiment. A display apparatus 1000 may include a touch panel 1003, a display panel 1005, a frame 1006, a circuit board 1007, and a battery 1008 between an upper cover 1001 and a lower cover 1009. The touch panel 1003 and the display panel 1005 are connected to flexible printed circuits (FPCs) 1002 and 1004, respectively. A transistor is printed on the circuit board 1007. The battery 1008 may not be provided unless the display apparatus 1000 is a mobile device, or may be provided at another position even when the display apparatus 1000 is a mobile device.

The display apparatus according to the present exemplary embodiment may include color filters having red, green, and blue colors. In the color filters, the red, green, and blue colors may be arranged in the delta arrangement.

The display apparatus according to the present exemplary embodiment may be used in a display unit of a mobile terminal. At this time, the display apparatus may have both a display function and an operation function. Examples of the mobile terminal include a mobile phone such as a smartphone, a tablet, and a head-mounted display.

The display apparatus according to the present exemplary embodiment may be used in a display unit of an imaging apparatus including an optical unit that includes a plurality of lenses, and an imaging element that receives light passing through the optical unit. The imaging apparatus may include a display unit that displays information acquired by the imaging element. The display unit may be a display unit exposed to outside the imaging apparatus, or may be a display unit placed in a viewfinder. The imaging apparatus may be a digital camera or a digital video camera.

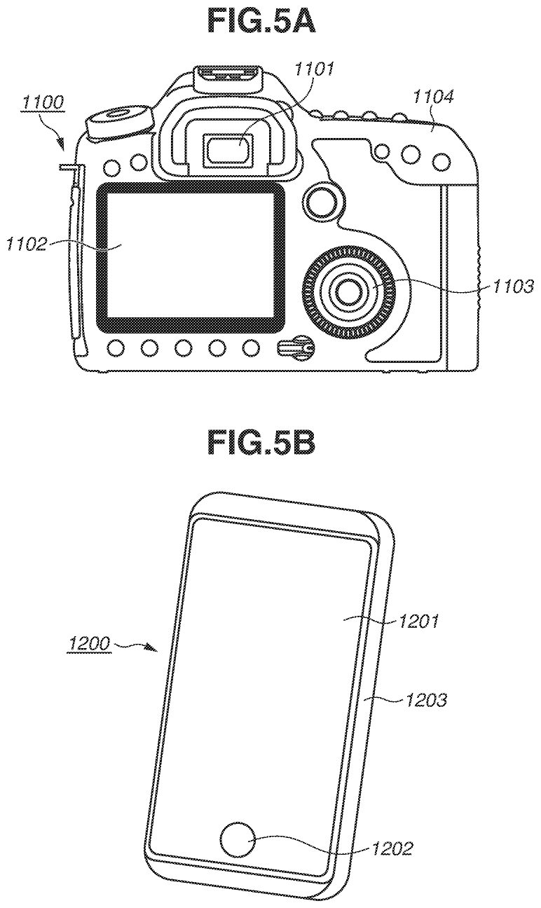

FIG. 5A is a schematic diagram illustrating an example of an imaging apparatus according to the present exemplary embodiment. An imaging apparatus 1100 may include a viewfinder 1101, a back surface display 1102, an operation unit 1103, and a housing 1104. The viewfinder 1101 may include a display apparatus according to the present exemplary embodiment. In this case, the display apparatus may display not only a captured image, but also environment information and an image capturing instruction. The environment information may include the intensity of external light, the direction of external light, the moving speed of an object, and the possibility that an object is blocked by a blocking object.

Since a timing suitable for capturing an image lasts for a short time, the information should be displayed as soon as possible. Thus, it is desirable to use a display apparatus using the organic light-emitting element according to the present invention. This is because the response speed of the organic light-emitting element is fast. The display apparatus using the organic light-emitting element can be used more suitably than a liquid crystal display apparatus in a case where the display apparatus is required to provide a fast display speed.

The imaging apparatus 1100 includes an optical unit (not illustrated). The optical unit includes a plurality of lenses and forms an image on an imaging element accommodated in the housing 1104. The focus can be adjusted by adjusting the relative positions between the plurality of lenses. This operation can also be performed automatically. The imaging apparatus 1100 may also be referred to as a “photoelectric conversion apparatus”. The photoelectric conversion apparatus can include a method for detecting the difference from the previous image without sequentially capturing images or a method for clipping an image from an always recorded image as an imaging method.

FIG. 5B is a schematic diagram illustrating an example of an electronic device according to the present exemplary embodiment. An electronic device 1200 includes a display unit 1201, an operation unit 1202, and a housing 1203. The housing 1203 may include a circuit, a printed circuit board including the circuit, a battery, and a communication unit. The operation unit 1202 may be a button, or may be a response unit using a touch panel method. The operation unit 1202 may be a biometric unit that recognizes a fingerprint and releases a lock. The electronic device 1200 including the communication unit can also be said to be a communication device. The electronic device 1200 may further have a camera function by including a lens and an imaging sensor. An image captured by the camera function is displayed on the display unit 1201. Examples of the electronic device 1200 include a smartphone and a laptop personal computer.

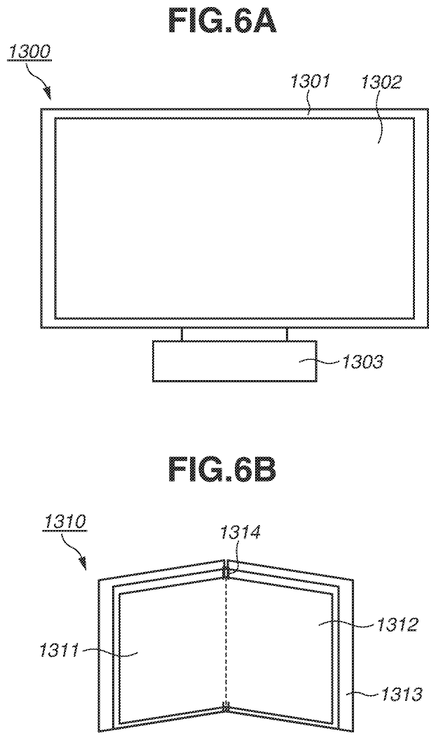

FIGS. 6A and 6B are schematic diagrams illustrating examples of a display apparatus according to the present exemplary embodiment. FIG. 6A illustrates a display apparatus such as a television monitor or a personal computer (PC) monitor. A display apparatus 1300 includes a frame 1301 and a display unit 1302. A light-emitting device according to the present exemplary embodiment may be used in the display unit 1302.

The display apparatus 1300 includes a base 1303 that supports the frame 1301 and the display unit 1302. The base 1303 is not limited to the form in FIG. 6A. The lower side of the frame 1301 may also serve as a base.

The frame 1301 and the display unit 1302 may be curved. The radius of curvature of the curve may be 5000 mm or more and 6000 mm or less.

FIG. 6B is a schematic diagram illustrating another example of the display apparatus according to the present exemplary embodiment. A display apparatus 1310 in FIG. 6B is configured to be folded and is a so-called foldable display apparatus. The display apparatus 1310 includes a first display unit 1311, a second display unit 1312, a housing 1313, and a folding point 1314. The first display unit 1311 and the second display unit 1312 may include the light-emitting device according to the present exemplary embodiment. The first display unit 1311 and the second display unit 1312 may be a single display apparatus without a joint. The first display unit 1311 and the second display unit 1312 can be divided at the folding point 1314. The first display unit 1311 and the second display unit 1312 may display images different from each other, or may display a single image.

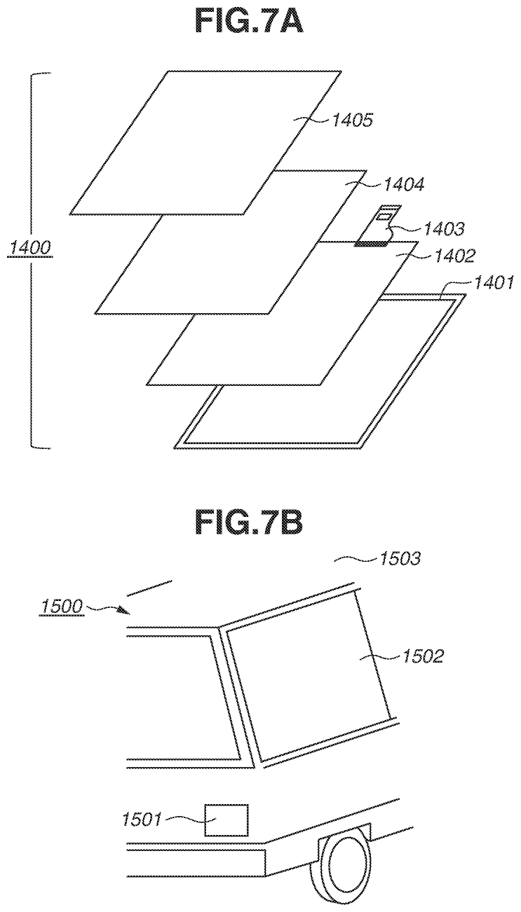

FIG. 7A is a schematic diagram illustrating an example of an illumination apparatus according to the present exemplary embodiment. An illumination apparatus 1400 may include a housing 1401, a light source 1402, a circuit board 1403, an optical film 1404, and a light diffusion portion 1405. The light source 1402 may include an organic light-emitting element according to the present exemplary embodiment. The optical film 1404 may be a filter for improving the color rendering properties of the light source 1402. The light diffusion portion 1405 can effectively diffuse light of the light source 1402 by lighting up and deliver light to a wide range. The optical film 1404 and the light diffusion portion 1405 may be provided on the light exit side of the illumination. A cover may be provided in an outermost portion of the illumination apparatus 1400, where necessary.

The illumination apparatus 1400 is, for example, an apparatus that illuminates the inside of a room. The illumination apparatus 1400 may emit light of white, daylight white, or any of colors from blue to red. The illumination apparatus 1400 may include a light modulation circuit that modulates the light. For example, the illumination apparatus 1400 may include the organic light-emitting element according to the present invention and a power supply circuit connected to the organic light-emitting element. The power supply circuit is a circuit that converts an alternating-current voltage into a direct-current voltage. The color temperature of white is 4200 K, and the color temperature of daylight white is 5000 K. The illumination apparatus 1400 may include a color filter.

The illumination apparatus 1400 according to the present exemplary embodiment may include a heat release portion. The heat release portion releases heat in the apparatus to outside the apparatus. Examples of the heat release portion include a metal having high specific heat and liquid silicon.

FIG. 7B is a schematic diagram illustrating an automobile as an example of a moving object according to the present exemplary embodiment. The automobile includes a taillight as an example of a lamp fitting. An automobile 1500 may include a taillight 1501 and have a form in which when a brake operation is performed, the automobile 1500 lights up the taillight 1501.

The taillight 1501 may include a light-emitting device according to the present exemplary embodiment. The taillight 1501 may include a protection member that protects an organic electroluminescent (EL) element. The material of the protection member does not matter so long as the material has somewhat high strength and is transparent. It is, however, desirable that the protection member should be composed of polycarbonate. The polycarbonate may be mixed with a furandicarboxylic acid derivative or an acrylonitrile derivative.

The automobile 1500 may include a vehicle body 1503 and a window 1502 attached to the vehicle body 1503. The window 1502 may be a transparent display if the window 1502 is not a window for confirming the front and the rear of the automobile 1500. The transparent display may include the light-emitting device according to the present exemplary embodiment. In this case, the constituent material of an electrode included in a light-emitting element is composed of a transparent member.

The moving object according to the present exemplary embodiment may be a vessel, an aircraft, or a drone. The moving object may include a body and a lamp fitting provided in the body. The lamp fitting may emit light to notify people of the position of the body. The lamp fitting includes the light-emitting device according to the present exemplary embodiment.

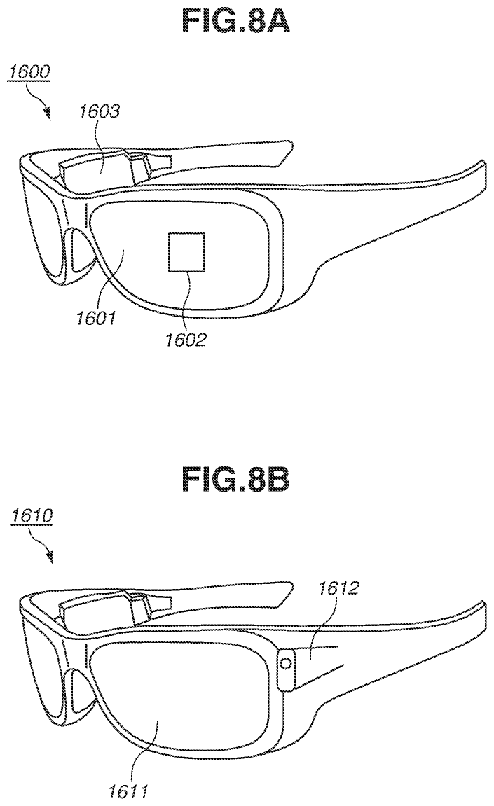

With reference to FIGS. 8A and 8B, application examples of the display apparatus according to each of the above exemplary embodiments will be described. The display apparatus can be applied to a system that can be worn as a wearable device such as smartglasses, a head-mounted display (HMD), or smart contact lenses. An imaging display apparatus used in such application examples includes an imaging apparatus capable of photoelectrically converting visible light and a display apparatus capable of emitting visible light.

FIG. 8A illustrates eyeglasses 1600 (smartglasses) according to an application example. On the front surface of a lens 1601 of the eyeglasses 1600, an imaging apparatus 1602 such as a complementary metal-oxide-semiconductor (CMOS) sensor or a single-photon avalanche diode (SPAD) is provided. On the back surface of the lens 1601, the display apparatus according to each of the above exemplary embodiments is provided.

The eyeglasses 1600 further include a control apparatus 1603. The control apparatus 1603 functions as a power supply that supplies power to the imaging apparatus 1602 and the display apparatus according to each of the exemplary embodiments. The control apparatus 1603 controls the operations of the imaging apparatus 1602 and the display apparatus. In the lens 1601, an optical system for collecting light on the imaging apparatus 1602 is formed.

FIG. 8B illustrates eyeglasses 1610 (smartglasses) according to an application example. The eyeglasses 1610 include a control apparatus 1612. On the control apparatus 1612, an imaging apparatus equivalent to the imaging apparatus 1602 and the display apparatus are mounted. In a lens 1611, an optical system for projecting light emitted from the imaging apparatus and the display apparatus in the control apparatus 1612 is formed. An image is projected onto the lens 1611. The control apparatus 1612 functions as a power supply that supplies power to the imaging apparatus and the display apparatus, and also controls the operations of the imaging apparatus and the display apparatus. The control apparatus 1612 may include a line-of-sight detection unit that detects the line of sight of a wearer (a user). The line of sight may be detected using infrared light. An infrared light-emitting unit emits infrared light to the eyeball of the user gazing at the display image. An imaging unit including a light-receiving element detects reflected light of the emitted infrared light from the eyeball, thereby obtaining a captured image of the eyeball. The control apparatus 1612 includes a reduction unit that reduces light from the infrared light-emitting unit to a display unit in a plan view, thereby reducing a decrease in the image quality.

The line of sight of the user to the display image is detected from the captured image of the eyeball obtained by capturing the infrared light. Any known technique can be applied to the line-of-sight detection using the captured image of the eyeball. As an example, a line-of-sight detection method based on a Purkinje image formed by the reflection of emitted light in the cornea can be used.

More specifically, a line-of-sight detection process based on a pupil-corneal reflection method is performed. Using the pupil-corneal reflection method, a line-of-sight vector indicating the direction (the rotation angle) of the eyeball is calculated based on an image of the pupil and a Purkinje image included in the captured image of the eyeball, thereby detecting the line of sight of the user.

A display apparatus according to an exemplary embodiment of the present invention may include an imaging apparatus including a light-receiving element and control a display image on the display apparatus based on line-of-sight information regarding a user from the imaging apparatus.

Specifically, based on the line-of-sight information, the display apparatus determines a first field-of-view area gazed at by the user and a second field-of-view area other than the first field-of-view area. The first and second field-of-view areas may be determined by a control apparatus of the display apparatus, or the display apparatus may receive the first and second field-of-view areas determined by an external control apparatus. In a display area of the display apparatus, the display resolution of the first field-of-view area may be controlled to be higher than the display resolution of the second field-of-view area. That is, the resolution of the second field-of-view area may be set to be lower than that of the first field-of-view area.

The display area includes a first display area and a second display area different from the first display area, and based on the line-of-sight information, an area having high priority is determined between the first and second display areas. The first and second display areas may be determined by the control apparatus of the display apparatus, or the display apparatus may receive the first and second display areas determined by the external control apparatus. The resolution of the area having high priority may be controlled to be higher than the resolution of an area other than the area having high priority. That is, the resolution of an area having relatively low priority may be set to be low.

The first field-of-view area and the area having high priority may be determined using artificial intelligence (AI). The AI may be a model configured to, using as teacher data an image of an eyeball and a direction actually viewed by the eyeball in the image, estimate the angle of the line of sight and the distance to an object in the line of sight based on an image of an eyeball. An AI program may be included in the display apparatus, or may be included in the imaging apparatus, or may be included in an external apparatus. In a case where the AI program is included in the external apparatus, the AI program is transmitted from the external apparatus to the display apparatus through communication.

In a case where display control is performed based on line-of-sight detection, the display apparatus can be suitably applied to smartglasses further including an imaging apparatus that captures outside. The smartglasses can display information regarding the captured outside in real time.

As described above, an apparatus using the organic light-emitting element according to the present exemplary embodiment is used, whereby it is possible to perform stable display even in long-time display with excellent image quality. Examples

Based on examples, the present invention will be described in further detail below.

### Example 1

After a transistor, wiring, an insulating layer, a pixel separation film, and a lower electrode (not illustrated) were formed on a silicon wafer substrate by a known technique, an organic compound layer composed of a hole transport layer, a light-emitting layer, and an electron transport layer, and an upper electrode were formed by a known technique.

Next, a protection layer was formed to cover substantially entire area of the surface of the substrate except for an external extraction electrode (not illustrated). Specifically, the substrate was heated to 110° C., the pressure of a reaction space between a high-frequency electrode and a ground electrode was controlled while mixed gas was caused to flow by plasma CVD, and high-frequency power was applied to the high-frequency electrode, thereby forming a film of a protection layer composed of silicon nitride. The mixed gas was composed of SiH₄, N₂, H₂, and NH₃. At this time, the film thickness of the protection layer was about 1.5 μm.

The prepared light-emitting device was caused to emit light, and the light emission luminance of the light-emitting device was measured. A simulated sunlight source that emitted visible light and ultraviolet light emitted light to the light-emitting device at an intensity of 1.5 AM for 8 hours. Then, the light emission luminance of the light-emitting device was measured again. The luminance after the emission was 0.95 times the luminance before the emission, and deteriorated.

Next, after 100 light-emitting devices were stored for 1000 hours under an environment with a temperature of 60° C. and a relative humidity of 90%, light emission from each of the light-emitting devices was measured. At this time, it was determined whether a non-lighting area which is an area where the light-emitting device did not light up occurred, and the number of light-emitting devices that normally emitted light without the occurrence of a non-lighting area was counted. As a result, all the 100 light-emitting devices normally lighted up.

The same protective film as the protection layer was formed on a silicon wafer. As a result of an ellipsometer measuring the absorption rate of the silicon wafer on which only the protective film was formed, the absorption rate at a wavelength of 450 nm was 0%, and the absorption rate at a wavelength of 380 nm was 10%.

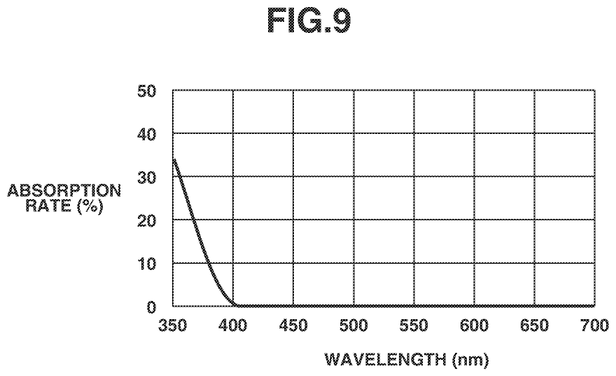

FIG. 9 is a graph illustrating the wavelength dependence of the absorption rate of the protection layer in example 1. In a region at a wavelength of 450 nm or more, the absorption rate is less than 1%, and therefore, it is possible to not only extract light emitted from the organic compound layer to outside the organic light-emitting device without absorbing the light emitted from the organic compound layer, but also reduce ultraviolet light.

Regarding the film formation of the protection layer, the protection layer in example 1 was prepared by adjusting parameters in the film formation so that the distance between the substrate and a gas distribution plate was in the range of 10 to 30 mm, the applied power was in the range of 0.1 to 1.5 W/cm², the SiH₄ gas flow rate was in the range of 0.01 to 0.3 sccm/cm², the N₂ gas flow rate was 0.2 to 6.0 sccm/cm², the H₂ gas flow rate was in the range of 0.2 to 6.0 sccm/cm², and the NH₃ gas flow rate was in the range of 0.0 to 0.6 sccm/cm².

In a case where a protection layer contains silicon nitride, it is considered that the absorption of visible light and ultraviolet light is related to the imperfection of the chemical bonding of the film, particularly, dangling bonding. As a method for easily measuring the imperfection of the silicon nitride film, the rate of dissolution of the silicon nitride film in an HF solution was measured. That is, the rate of dissolution of the silicon wafer on which the protective film was formed in a 1% HF solution was measured. In the measuring method, after the film thickness of the silicon wafer before the dissolution was measured using the ellipsometer, the silicon wafer was immersed in a 1% HF solution at 25° C. for 10 to 120 seconds. Then, after the silicon wafer was water-washed, the film thickness of the silicon wafer was measured again, and the rate of dissolution was determined based on the difference in the film thickness before and after the immersion. As a result, the rate of dissolution was 80 nm/min.

### Example 2

A light-emitting device was prepared similarly to example 1 except that the absorption rate of the protection layer at a wavelength of 450 nm was 0%, and the absorption rate of the protection layer at a wavelength of 380 nm was 25%. The rate of dissolution in 1% HF was 500 nm/min.

The light emission luminance before the emission from the simulated sunlight source was 1.0 times that in example 1, and the luminance after the emission from the simulated sunlight source was 0.98 times the light emission luminance before the emission in example 1. The number of light-emitting devices that normally emitted light after light-emitting devices were stored for 1000 hours under an environment with a temperature of 60° C. and a relative humidity of 90% was 100 out of 100 light-emitting devices. That is, the proportion of devices was 100%.

### Example 3

A light-emitting device was prepared similarly to example 1 except that the absorption rate of the protection layer at a wavelength of 450 nm was 0%, and the absorption rate of the protection layer at a wavelength of 380 nm was 38%. The rate of dissolution in 1% HF was 2000 nm/min.

The light emission luminance before the emission from the simulated sunlight source was 1.0 times that in example 1, and the luminance after the emission from the simulated sunlight source was 0.99 times the light emission luminance before the emission in example 1. The number of light-emitting devices that normally emitted light after light-emitting devices were stored for 1000 hours under an environment with a temperature of 60° C. and a relative humidity of 90% was 100 out of 100 light-emitting devices. That is, the proportion of devices was 100%.

### Comparative Example 1

A light-emitting device was prepared similarly to example 1 except that the absorption rate of the protection layer at a wavelength of 450 nm was 0%, and the absorption rate of the protection layer at a wavelength of 380 nm was 5%. The rate of dissolution in 1% HF was 50 nm/min.

The light emission luminance before the emission from the simulated sunlight source was 1.0 times that in example 1, and the luminance after the emission from the simulated sunlight source was 0.6 times the light emission luminance before the emission in example 1. The number of light-emitting devices that normally emitted light after light-emitting devices were stored for 1000 hours under an environment with a temperature of 60° C. and a relative humidity of 90% was 100 out of 100 light-emitting devices. That is, the proportion of devices was 100%.

### Comparative Example 2

A light-emitting device was prepared similarly to example 1 except that the absorption rate of the protection layer at a wavelength of 450 nm was 0%, and the absorption rate of the protection layer at a wavelength of 380 nm was 0%. The rate of dissolution in 1% HF was 10 nm/min.

The light emission luminance before the emission from the simulated sunlight source was 1.0 times that in example 1, and the luminance after the emission from the simulated sunlight source was 0.3 times the light emission luminance before the emission in example 1. The number of light-emitting devices that normally emitted light after light-emitting devices were stored for 1000 hours under an environment with a temperature of 60° C. and a relative humidity of 90% was 100 out of 100 light-emitting devices. That is, the proportion of devices was 100%.

### Comparative Example 3

A light-emitting device was prepared similarly to example 1 except that the absorption rate of the protection layer at a wavelength of 450 nm was 7%, and the absorption rate of the protection layer at a wavelength of 380 nm was 50%. The rate of dissolution in 1% HF was 3000 nm/min.

The light emission luminance before the emission from the simulated sunlight source was 0.93 times that in example 1, and the luminance after the emission from the simulated sunlight source was 0.93 times the light emission luminance before the emission in example 1. The number of light-emitting devices that normally emitted light after light-emitting devices were stored for 1000 hours under an environment with a temperature of 60° C. and a relative humidity of 90% was 63 out of 100 light-emitting devices. That is, the proportion of devices was 63%.

### Comparative Example 4

A light-emitting device was prepared similarly to example 1 except that the absorption rate of the protection layer at a wavelength of 450 nm was 20%, and the absorption rate of the protection layer at a wavelength of 380 nm was 71%. The rate of dissolution in 1% HF was 5000 nm/min.

The light emission luminance before the emission from the simulated sunlight source was 0.8 times that in example 1, and the luminance after the emission from the simulated sunlight source was 0.8 times the light emission luminance before the emission in example 1. The number of light-emitting devices that normally emitted light after light-emitting devices were stored for 1000 hours under an environment with a temperature of 60° C. and a relative humidity of 90% was 28 out of 100 light-emitting devices. That is, the proportion of devices was 28%.

### Example 4

After the silicon nitride film according to example 1 was formed, an aluminum oxide film was formed by the ALD using trimethylaluminum and water as precursors, thereby obtaining a laminated film of silicon nitride and aluminum oxide as the protection layer. The film thickness of aluminum oxide was about 200 nm.

The absorption rate of the protection layer at a wavelength of 450 nm was 0%, and the absorption rate of the protection layer at a wavelength of 380 nm was 10%.

The light emission luminance before the emission from the simulated sunlight source was 1.0 times that in example 1, and the luminance after the emission from the simulated sunlight source was 0.95 times the light emission luminance before the emission in example 1. The number of light-emitting devices that normally emitted light after light-emitting devices were stored for 1000 hours under an environment with a temperature of 60° C. and a relative humidity of 90% was 100 out of 100 light-emitting devices. That is, the proportion of devices was 100%.

### Example 5

After the silicon nitride film according to example 2 was formed, an aluminum oxide film was formed by the ALD using trimethylaluminum and water as precursors, thereby obtaining a laminated film of silicon nitride and aluminum oxide as the protection layer. The film thickness of aluminum oxide was about 200 nm.

The absorption rate of the protection layer at a wavelength of 450 nm was 0%, and the absorption rate of the protection layer at a wavelength of 380 nm was 26%.

The light emission luminance before the emission from the simulated sunlight source was 1.0 times that in example 1, and the luminance after the emission from the simulated sunlight source was 0.98 times the light emission luminance before the emission in example 1. The number of light-emitting devices that normally emitted light after light-emitting devices were stored for 1000 hours under an environment with a temperature of 60° C. and a relative humidity of 90% was 100 out of 100 light-emitting devices. That is, the proportion of devices was 100%.

### Example 6

After the silicon nitride film according to example 3 was formed, an aluminum oxide film was formed by the ALD using trimethylaluminum and water as precursors, thereby obtaining a laminated film of silicon nitride and aluminum oxide as the protection layer. The film thickness of aluminum oxide was about 200 nm.

The absorption rate of the protection layer at a wavelength of 450 nm was 0%, and the absorption rate of the protection layer at a wavelength of 380 nm was 40%.

The light emission luminance before the emission from the simulated sunlight source was 1.0 times that in example 1, and the luminance after the emission from the simulated sunlight source was 0.99 times the light emission luminance before the emission in example 1. The number of light-emitting devices that normally emitted light after light-emitting devices were stored for 1000 hours under an environment with a temperature of 60° C. and a relative humidity of 90% was 100 out of 100 light-emitting devices. That is, the proportion of devices was 100%.

### Comparative Example 5

After the silicon nitride film according to comparative example 1 was formed, an aluminum oxide film was formed by the ALD using trimethylaluminum and water as precursors, thereby obtaining a laminated film of silicon nitride and aluminum oxide as the protection layer. The film thickness of aluminum oxide was about 200 nm.

The absorption rate of the protection layer at a wavelength of 450 nm was 0%, and the absorption rate of the protection layer at a wavelength of 380 nm was 5%.

The light emission luminance before the emission from the simulated sunlight source was 1.0 times that in example 1, and the luminance after the emission from the simulated sunlight source was 0.6 times the light emission luminance before the emission in example 1. The number of light-emitting devices that normally emitted light after light-emitting devices were stored for 1000 hours under an environment with a temperature of 60° C. and a relative humidity of 90% was 100 out of 100 light-emitting devices. That is, the proportion of devices was 100%.

### Comparative Example 6

After the silicon nitride film according to comparative example 2 was formed, an aluminum oxide film was formed by the ALD using trimethylaluminum and water as precursors, thereby obtaining a laminated film of silicon nitride and aluminum oxide as the protection layer. The film thickness of aluminum oxide was about 200 nm.

The absorption rate of the protection layer at a wavelength of 450 nm was 0%, and the absorption rate of the protection layer at a wavelength of 380 nm was 0%.

The light emission luminance before the emission from the simulated sunlight source was 1.0 times that in example 1, and the luminance after the emission from the simulated sunlight source was 0.3 times the light emission luminance before the emission in example 1. The number of light-emitting devices that normally emitted light after light-emitting devices were stored for 1000 hours under an environment with a temperature of 60° C. and a relative humidity of 90% was 100 out of 100 light-emitting devices. That is, the proportion of devices was 100%.

### Comparative Example 7

After the silicon nitride film according to comparative example 3 was formed, an aluminum oxide film was formed by the ALD using trimethylaluminum and water as precursors, thereby obtaining a laminated film of silicon nitride and aluminum oxide as the protection layer. The film thickness of aluminum oxide was about 200 nm.

The absorption rate of the protection layer at a wavelength of 450 nm was 8%, and the absorption rate of the protection layer at a wavelength of 380 nm was 50%.

The light emission luminance before the emission from the simulated sunlight source was 0.92 times that in example 1, and the luminance after the emission from the simulated sunlight source was 0.92 times the light emission luminance before the emission in example 1. The number of light-emitting devices that normally emitted light after light-emitting devices were stored for 1000 hours under an environment with a temperature of 60° C. and a relative humidity of 90% was 95 out of 100 light-emitting devices. That is, the proportion of devices was 95%.

### Comparative Example 8

After the silicon nitride film according to comparative example 3 was formed, an aluminum oxide film was formed by the ALD using trimethylaluminum and water as precursors, thereby obtaining a laminated film of silicon nitride and aluminum oxide as the protection layer. The film thickness of aluminum oxide was about 200 nm.

The absorption rate of the protection layer at a wavelength of 450 nm was 21%, and the absorption rate of the protection layer at a wavelength of 380 nm was 72%.

The light emission luminance before the emission from the simulated sunlight source was 0.78 times that in example 1, and the luminance after the emission from the simulated sunlight source was 0.78 times the light emission luminance before the emission in example 1. The number of light-emitting devices that normally emitted light after light-emitting devices were stored for 1000 hours under an environment with a temperature of 60° C. and a relative humidity of 90% was 78 out of 100 light-emitting devices. That is, the proportion of devices was 78%.

Table 1 illustrates the results of examples 1 to 6 and comparative examples 1 to 8. In the determination in table 1, a level that satisfied all of the conditions that the luminance before the emission of the simulated sunlight was 0.95 or more, that the luminance after the emission of the simulated sunlight was 0.95 or more, and that the number of light-emitting devices that normally emitted light after light-emitting devices were stored at a high temperature and a high humidity was 100 out of 100 light-emitting devices was determined as “pass”. A level that did not satisfy any one of these evaluation items was not suitable as a light-emitting device, and therefore was determined as “fail”.

TABLE 1

| | | | | | | Proportion | | |
|---|---|---|---|---|---|---|---|---|
| | | | | | | of devices | | |
| | | | | | | that normally | | |
| | | | | | | emitted | | |
| | | | | | | light after | | |
| | | | | Relative | Relative | devices | | |
| | | | | luminance | luminance | were stored | | |
| | | Light | Light | before | after | at high | Rate of | |
| | | absorption | absorption | emission of | emission of | temperature | dissolution | |
| | Film | rate | rate | simulated | simulated | and high | of SiN | |
| | configuration | @450 nm | @380 nm | sunlight | sunlight | humidity | (nm/min) | Determination |
| Example 1 | SiN (1.5 μm) | 0% | 10% | 1 | 0.95 | 100% | 80 | pass |
| Example 2 | SiN (1.5 μm) | 0% | 25% | 1 | 0.98 | 100% | 500 | pass |
| Example 3 | SiN (1.5 μm) | 0% | 38% | 1 | 0.99 | 100% | 2000 | pass |
| Comparative | SiN (1.5 μm) | 0% | 5% | 1 | 0.6 | 100% | 50 | fail |
| example 1 | | | | | | | | |
| Comparative | SiN (1.5 μm) | 0% | 0% | 1 | 0.3 | 100% | 10 | fail |
| example 2 | | | | | | | | |
| Comparative | SiN (1.5 μm) | 7% | 50% | 0.93 | 0.93 | 63% | 3000 | fail |
| example 3 | | | | | | | | |
| Comparative | SiN (1.5 μm) | 20% | 71% | 0.8 | 0.8 | 28% | 5000 | fail |
| example 4 | | | | | | | | |
| Example 4 | SiN (1.5 μm), | 0% | 10% | 1 | 0.95 | 100% | 80 | pass |
| | Al2O3 | | | | | | | |
| | (200 nm) | | | | | | | |
| Example 5 | SiN (1.5 μm), | 0% | 26% | 1 | 0.98 | 100% | 500 | pass |
| | Al2O3 | | | | | | | |
| | (200 nm) | | | | | | | |
| Example 6 | SiN (1.5 μm), | 0% | 40% | 1 | 0.99 | 100% | 2000 | pass |
| | Al2O3 | | | | | | | |
| | (200 nm) | | | | | | | |
| Comparative | SiN (1.5 μm), | 0% | 5% | 1 | 0.6 | 100% | 50 | fail |
| example 5 | Al2O3 | | | | | | | |
| | (200 nm) | | | | | | | |
| Comparative | SiN (1.5 μm), | 0% | 0% | 1 | 0.3 | 100% | 10 | fail |
| example 6 | Al2O3 | | | | | | | |
| | (200 nm) | | | | | | | |
| Comparative | SiN (1.5 μm), | 8% | 50% | 0.92 | 0.92 | 95% | 3000 | fail |
| example 7 | Al2O3 | | | | | | | |
| | (200 nm) | | | | | | | |
| Comparative | SiN (1.5 μm), | 21% | 72% | 0.78 | 0.78 | 78% | 5000 | fail |
| example 8 | Al2O3 | | | | | | | |
| | (200 nm) | | | | | | | |

As described above, the light-emitting device according to the present invention reduces the absorption of visible light and absorbs ultraviolet light, and therefore includes a protection layer that protects a light-emitting element. As a result, it is possible to provide a light-emitting device that protects a light-emitting element over a long period.

The present invention is not limited to the above exemplary embodiments, and can be changed and modified in various ways without departing from the spirit and the scope of the present invention. Thus, the following claims are appended to publicize the scope of the present invention.

According to the present invention, it is possible to provide a light-emitting device including a protection layer that protects a light-emitting element over a long period.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. A light-emitting device comprising:
a light-emitting element; and
a protection layer covering the light-emitting element and composed of an inorganic compound,
wherein a light absorption rate of the protection layer at a wavelength of 450 nm is less than 7%, and the light absorption rate of the protection layer at a wavelength of 380 nm is 5% or more.

2. The light-emitting device according to claim 1, wherein a rate of dissolution of the protection layer in 1% hydrogen fluoride (HF) at 25° C. is 80 nm/min or more and 2000 nm/min or less.

3. The light-emitting device according to claim 1, wherein the light absorption rate of the protection layer at a wavelength of 450 nm is less than 1%.

4. The light-emitting device according to claim 1, wherein the light absorption rate of the protection layer at a wavelength of 380 nm is 10% or more.

5. A light-emitting device comprising:
a light-emitting element; and
a protection layer covering the light-emitting element and composed of an inorganic compound,
wherein a rate of dissolution of the protection layer in 1% HF at 25° C. is 80 nm/min or more and 2000 nm/min or less.

6. The light-emitting device according to claim 1, wherein the protection layer contains a first layer composed only of silicon nitride.

7. The light-emitting device according to claim 1, wherein the protection layer contains a layer composed only of aluminum oxide.

8. The light-emitting device according to claim 1, wherein the protection layer consists only of a layer composed only of silicon nitride and a layer composed only of aluminum oxide.

9. The light-emitting device according to claim 8, wherein the protection layer includes a first layer composed only of silicon nitride, a layer composed only of aluminum oxide, and a second layer composed only of silicon nitride in this order.

10. The light-emitting device according to claim 8, wherein the protection layer includes a layer composed only of aluminum oxide, a first layer composed only of silicon nitride, a layer composed only of aluminum oxide, and a second layer composed only of silicon nitride in this order.

11. The light-emitting device according to claim 8, wherein the protection layer includes a layer composed only of aluminum oxide, a first layer composed only of silicon nitride, and a second layer composed only of silicon nitride in this order.

12. The light-emitting device according to claim 11, wherein a density of the first layer composed only of silicon nitride and a density of the second layer composed only of silicon nitride are different from each other.

13. The light-emitting device according to claim 9, wherein a rate of dissolution of the first layer composed only of silicon nitride in 1% HF at 25° C. is 80 nm/min or more and 2000 nm/min or less.

14. The light-emitting device according to claim 9, wherein rates of dissolution of the first layer composed only of silicon nitride and the second layer composed only of silicon nitride in 1% HF at 25° C. are 80 nm/min or more and 2000 nm/min or less.

15. The light-emitting device according to claim 1, wherein the protection layer includes a plurality of layers, and rates of dissolution of all the plurality of layers in 1% HF at 25° C. are 80 nm/min or more and 2000 nm/min or less.

16. The light-emitting device according to claim 1, wherein a layer thickness of the protection layer is 0.5 μm or more and 5.0 μm or less.

17. The light-emitting device according to claim 1, wherein the light-emitting element is an organic light-emitting element including a first electrode, an organic compound layer containing a light-emitting layer, and a second electrode in this order.

18. The light-emitting device according to claim 1, wherein the light-emitting device includes a resin layer on the protection layer.

19. The light-emitting device according to claim 18, wherein the light-emitting device includes a color filter on the resin layer.

20. The light-emitting device according to claim 1, wherein the light-emitting device includes a color filter on the protection layer.

21. A display apparatus comprising:
the light-emitting device according to claim 1; and
a display control apparatus connected to the light-emitting device.

22. An imaging apparatus comprising:
an optical unit including a plurality of lenses;
an imaging sensor configured to receive light passing through the optical unit; and
a display unit configured to display an image captured by the imaging sensor,
wherein the display unit includes the light-emitting device according to claim 1.

23. An electronic device comprising:
a display unit including the light-emitting device according to claim 1;
a housing in which the display unit is provided; and
a communication unit provided in the housing and configured to communicate with outside.

24. An illumination apparatus comprising:
a light source including the light-emitting device according to claim 1; and
a light diffusion unit or an optical film configured to transmit light emitted from the light source.

25. A moving object comprising:
a lamp fitting including the light-emitting device according to claim 1; and
a body in which the lamp fitting is provided.
